(19) United States
(12) Patent Application Publication
(10) Pub. No.: US 2024/0032184 A1
(43) Pub. Date: Jan. 25, 2024

(54) IMPROVED ELECTRONIC COMPONENT PACKAGE ARRANGEMENT

(71) Applicant: Telefonaktiebolaget LM Ericsson (publ), Stockholm (SE)

(72) Inventors: Göran Snygg, Partille (SE); Daniel Sjöberg, Mölndal (SE)

(21) Appl. No.: 18/268,416

(22) PCT Filed: Dec. 22, 2020
(86) PCT No.: PCT/EP2020/087580

§ 371 Date: Jun. 20, 2023

(51) Int. Cl. H05K 1/02; H01L 23/498; H01L 23/00; H05K 7/20

(52) U.S. Cl. CPC H05K 1/0204; H01L 23/4985; H05K 1/0209; H01L 24/16; H05K 7/20509; H01L 23/3736

(57) ABSTRACT

The present disclosure relates to an electronic component package arrangement comprising an integrated circuit (IC), a metal carrier and at least one flexible conductor device. The IC has an IC mounting surface and the metal carrier has a carrier mounting surface with an area that exceeds an area of the IC mounting surface, where the mounting surfaces are mounted to each other. The flexible conductor device is placed between the IC and the metal carrier and comprises a metallization that is carried on a flexible dielectric carrier material. The metallization forms flexible conductor tracks to which the IC is electrically connected and lead from the IC to a position distanced from the metal carrier such that the flexible conductor tracks can be electrically connected to an external device.

### TECHNICAL FIELD

The present disclosure relates to an electronic component package arrangement comprising an integrated circuit and a metal carrier onto which the integrated circuit is mounted.

### BACKGROUND

Generally, electronics are sensitive for heat where electronic components in principle get a reduced life time with higher temperature. Furthermore, the efficiency for active electronic components also gets reduced in with higher temperature, and their electrical performance can deteriorate. For most types of electronic components, the aging is accelerating with higher temperatures. Typically, 10° C. difference around 20° C. has less impact on component life time than 100 around 70° C.

High temperatures could also lead to a sudden death phenomenon when a maximum rating for an electronic component is reached. A combination of aging and poor derating could also lead to this type of sudden death of an electronic component. Therefore, it is most important to avoid the highest peak temperatures, and by providing an increased cooling for electronic components, these types of phenomena can be avoided.

Products for the telecommunication business are to a large extent comprised in outdoor equipment, and a trend in telecom and many other electronic products is that the devices shrink in size, which often leads to increased temperatures inside the housings. Some environments are tougher than other, for example areas with big temperature variation, and in particular products aimed for outdoor use are exposed for environmental strain.

There are different solutions for cooling electronic components, for example using electronic components aimed to be mounted in a cavity in a metal back/hard back PCB (Printed Circuit Board). Connecting a metal carrier positioned on a component package to a metal back/hard back PCB gives good thermal performance, especially if the metal surfaces are soldered together. This, however, requires meeting height tolerances for the component package which adds additional cost for each component package.

Another type of component package is a so-called plastic over-mold component package which is aimed for surface mounting, meaning they are attached to one plane. Here, a so-called metal coin, a metal insert, is placed inside the PCB. These coins are relative costly and affect tolerance requirements for the PCB. These coins are smaller in area than the component package which limits power handling capability. Therefore, this type of packages is not very useful for high power applications.

It is desired to provide electronic component package arrangement that is adapted for relatively high temperatures in a more efficient and cost-effective manner than previous solutions.

### SUMMARY

It is an object of the present disclosure to provide an electronic component package arrangement that is adapted for relatively high temperatures in a more efficient and cost-effective manner than previous solutions.

This object is obtained by means of an electronic component package arrangement comprising an integrated circuit (IC), a metal carrier and at least one flexible conductor device. The IC has an IC mounting surface and the metal carrier has a carrier mounting surface with an area that exceeds an area of the IC mounting surface, where the IC mounting surface is mounted to a part of the carrier mounting surface. The flexible conductor device is placed between the IC and the metal carrier and comprises a metallization that is carried on a flexible dielectric carrier material. The metallization forms flexible conductor tracks to which the IC is electrically connected, the flexible conductor tracks leading from the IC to a position distanced from the metal carrier such that the flexible conductor tracks can be electrically connected to an external device.

This means that the IC can be connected to the external device although the metal carrier has a carrier mounting surface S_{c} with an area that exceeds an area of the IC mounting surface, such that the metal carrier can have a larger size than a corresponding quad-flat no-leads (QFN), or dual-flat no-leads (DFN), lead frame, as the transitions to the external device are provided outside the packaging contour. Consequently, since the metal carrier can be made larger than previously possible by means of the flexible conductor devices an enhanced cooling of the IC can be obtained, and the thermal performance will be superior compared to prior package technologies without driving the tolerance chains with the associated costs.

According to some aspects, the external device is a printed circuit board (PCB) where the flexible conductor tracks are adapted to be electrically connected to external conductor tracks that are provided on the PCB.

This way, the present disclosure can be applied to all types of PCB technology.

According to some aspects, where the package arrangement comprises a cover part, adapted to cover the IC.

This way, the IC is protected from the environment.

According to some aspects, the PCB comprises a metal layer onto which the metal carrier at least partly is adapted to be placed.

This way, a ground plane, heat dissipation and mechanical rigidity can be provided.

According to some aspects, the PCB comprises a metal insert onto which the metal carrier at least partly is adapted to be placed.

This way, heat dissipation, possibly to a cooling flange that is in thermal contact with the metal insert, can be provided.

According to some aspects, the package arrangement comprises a first intermediate resilient thermally conductive material placed on a side of the metal carrier that faces the PCB.

This is advantageous for components and circuitry that are sensitive for impact such as vibration, knocking and other microphonic effects since these will be attenuated and cause less or not at all impact.

According to some aspects, the package arrangement comprises a second intermediate resilient thermally conductive material placed between the cover part and the PCB.

In addition to said attenuation, this enables the metal carrier to dissipate heat away from the PCB which can be advantageous in cases when it is not suitable or sufficient to use a metal layer and/or a metal insert. This can for example be due to mechanical and/or thermal properties of the PCB and/or surrounding components.

According to some aspects, the package arrangement comprises a metal heatsink that is thermally connected to the metal carrier, the metal heatsink being larger than the metal carrier.

This way, an increased heat dissipation is enabled.

According to some aspects, the package arrangement comprises a third intermediate resilient thermally conductive material placed between the metal heatsink and the metal carrier.

This way, vibrations that are inflicted at the metal heatsink are attenuated.

According to some aspects, at least one resilient thermally conductive material is constituted by silicon rubber or a thermally conductive paste.

Many different materials and compounds can thus be used in this application.

According to some aspects, the PCB comprises an aperture through which at least one protruding part of an external cooling flange structure protrudes, where the metal carrier at least partly is adapted to be placed on a part of the protruding part.

This is advantageous when cooling requirements are relatively high and/or if the package arrangement is used in a larger structure with integrated cooling flanges.

According to some aspects, the IC comprises ball grid array (BGA) connections that are connected to the flexible conductor tracks of the flexible conductor device.

This way, cooling is improved, normally being a problem for BGA packages.

This object is also obtained by means of microwave link transceiver arrangements and methods which are associated with the above advantages.

### BRIEF DESCRIPTION OF THE DRAWINGS

The present disclosure will now be described more in detail with reference to the appended drawings, where:

FIG. 1 schematically shows a partially exploded perspective side view of an electronic component package arrangement;

FIG. 2 schematically shows a cut-open side view of an electronic component package arrangement according to a first example;

FIG. 3 schematically shows a cut-open side view of an electronic component package arrangement according to a second example;

FIG. 4 schematically shows a cut-open side view of an electronic component package arrangement according to a third example;

FIG. 5 schematically shows a cut-open side view of an electronic component package arrangement according to a fourth example;

FIG. 6 schematically shows a cut-open side view of an electronic component package arrangement according to a fifth example;

FIG. 7 schematically shows a cut-open side view of a microwave link transceiver arrangement comprising two electronic component package arrangements according to the present disclosure, and

FIG. 8 shows a flowchart for methods according to the present disclosure.

### DETAILED DESCRIPTION

Aspects of the present disclosure will now be described more fully hereinafter with reference to the accompanying drawings. The different devices, systems, computer programs and methods disclosed herein can, however, be realized in many different forms and should not be construed as being limited to the aspects set forth herein. Like numbers in the drawings refer to like elements throughout.

The terminology used herein is for describing aspects of the disclosure only and is not intended to limit the invention. As used herein, the singular forms “a”, “an” and “the” are intended to include the plural forms as well, unless the context clearly indicates otherwise.

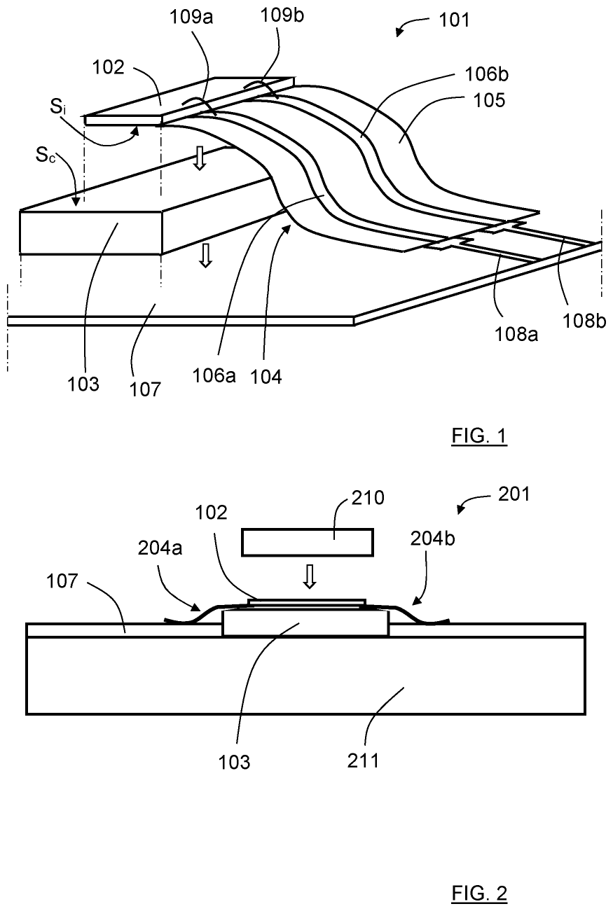

The following initial description refers to FIG. 1 and FIG. 2, where FIG. 1 schematically shows a partially exploded perspective side view of an electronic component package arrangement and FIG. 2 schematically shows a cut-open side view of an electronic component package arrangement according to a first example.

There is an electronic component package arrangement 101 comprising an integrated circuit 102, IC, a metal carrier 103 and at least one flexible conductor device 104; 204a, 204b. In FIG. 1, one flexible conductor device 104 is shown, but as depicted in FIG. 2 there can be two or even more flexible conductor devices 204a, 204b.

The IC 102 has an IC mounting surface Sᵢ and the metal carrier 103 has a carrier mounting surface S_{c} with an area that exceeds an area of the IC mounting surface Sᵢ. The IC mounting surface Sᵢ is mounted to a part of the carrier mounting surface S_{c}, the mounting surfaces Sᵢ, S_{c} facing each other. According to the present disclosure, the flexible conductor device 104; 204a, 204b is placed between the IC 102 and the metal carrier 103 and comprises a metallization 106a, 106b that is carried on a flexible dielectric carrier material 105. The metallization forms flexible conductor tracks 106a, 106b to which the IC 102 is electrically connected, the flexible conductor tracks 106a, 106b leading from the IC 102 to a position distanced from the metal carrier 103 such that the flexible conductor tracks 106a, 106b can be electrically connected to an external device 107.

The flexible conductor devices 104; 204a, 204b enable the IC 102 to be connected to the external device 107 although the metal carrier 103 has a carrier mounting surface S_{c} with an area that exceeds an area of the IC mounting surface Sᵢ.

The metal carrier 103 mounting surface S_{c} having an area that exceeds the area of the IC mounting surface Sᵢ means that the metal carrier 103 can have a larger size than a corresponding quad-flat no-leads (QFN), or dual-flat no-leads (DFN), lead frame, as the transitions to the external device 107 are provided outside the packaging contour. Since the metal carrier 103 can be made larger than previously possible by means of the flexible conductor devices 104; 204a, 204b, an enhanced cooling of the IC 102 can be obtained.

The IC 102 can for example be glued or soldered to the metal carrier 102 which will result in a connection with very low thermal resistance. By means of the present disclosure, the thermal performance will be superior compared to prior package technologies without driving the tolerance chains with the associated costs. According to some aspects, the flexible conductor devices 104; 204a, 204b can be constituted by commercially available Kapton tape with copper traces, which is very flexible and easy to shape.

According to some aspects, the external device is a printed circuit board 107 (PCB), where the flexible conductor tracks 106a, 106b are adapted to be electrically connected to external conductor tracks 108a, 108b that are provided on the PCB 107. The flexible conductor tracks 106a, 106b can for example be soldered to the external conductor tracks 108a, 108b.

The flexible conductor tracks 106a, 106b can be electrically connected to the IC 102 in many ways, for example directly, for example to a lead-fame, or via bond wires 109a, 109b as illustrated in FIG. 1.

It is to be noted that FIG. 1 is a simplified presentation of an example of the electronic component package arrangement 101 according to the present disclosure, intended to illustrate the principle behind the electronic component package arrangement according to the present disclosure. For example there can be two or more flexible conductor devices 104, each flexible conductor devices 104 comprising more than two flexible conductor tracks 106a, 106b that are connected to corresponding external conductor tracks 108a, 108b.

According to some aspects, as shown in FIG. 2, the package arrangement comprises a cover part 210, adapted to cover the IC 102. The cover part can for example be plastic or ceramic part that is placed over the IC 102, or a plastic mold.

According to some aspects, as shown in FIG. 2, the PCB comprises a metal layer 211 onto which the metal carrier 103 at least partly is adapted to be placed. The metal layer 211 can be in the form of a so-called metal hardback that both provides a ground plane, heat dissipation and mechanical rigidity. The metal carrier 103 is either placed directly on the metal layer 211 or via one or more intermediate parts as will be discussed below, the metal layer 211 being reached via an aperture in the PCB.

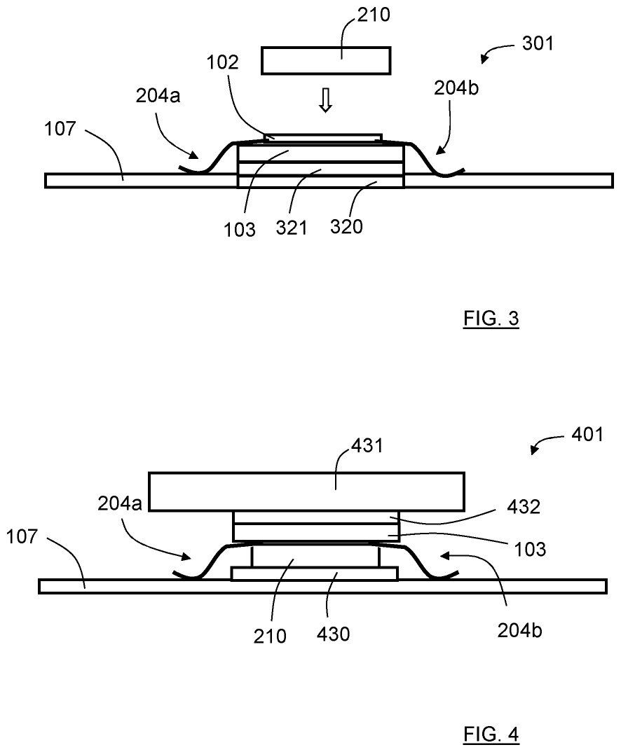

According to some aspects, as shown in FIG. 3 that illustrates a second example, the PCB comprises a metal insert 320 onto which the metal carrier 103 at least partly is adapted to be placed. The metal carrier 103 is either placed directly on the metal insert 320, or via one or more intermediate parts as will be discussed below. The metal insert 320 can provide heat dissipation, possibly to a cooling flange that is in thermal contact with the metal insert 320. The metal insert 320 can be combined with a metal layer 211 as discussed able.

The package arrangement 301 according to the present disclosure also enables the IC 102 to be mechanically isolated from rest of the structure by means of the flexible conductor devices 204a, 204b as will be described in the following examples.

According to some aspects, with continued reference to FIG. 3, the package arrangement 301 comprises a first intermediate resilient thermally conductive material 321 placed on a side of the metal carrier 103 that faces the PCB 107. Heat can then be transferred both to and from the metal carrier 103. Adding such an intermediate material 321 is very advantageous, for example for oscillators that are sensitive for impact such as vibration, knocking and other microphonic effects since these will be attenuated and cause less or not at all impact.

According to some aspects, with reference to FIG. 4 that illustrates a third example, the package arrangement 401 comprises a second intermediate resilient thermally conductive material 430 placed between the cover part 210 and the PCB 107. Here, the cover part 210 is positioned on the PCB 107, via the second intermediate material 430, and the metal carrier 103 is positioned on a side of cover 103 that faces away from the PCB 107. The metal carrier 103 is then enabled to dissipate heat away from the PCB 107. This can be advantageous in cases when it is not suitable or sufficient to use a metal layer 211 and/or a metal insert 320, for example due to mechanical and/or thermal properties of the PCB 107 and/or surrounding components.

According to some further aspects, the package arrangement 401 comprises a metal heatsink 431 that is thermally connected to the metal carrier 103, the metal heatsink 431 being larger than the metal carrier 103. The metal heatsink 431 can either be directly or indirectly connected to the metal carrier 103; according to some aspects, the package arrangement 401 comprises a third intermediate resilient thermally conductive material 432 placed between the metal heatsink 431 and the metal carrier 103. The third intermediate material 432 can for example attenuate vibrations that are inflicted at the relatively large metal heatsink 431.

According to some further aspects, at least one resilient thermally conductive material 321, 430, 432 is constituted by silicon rubber or a thermally conductive paste. Other types of such materials and compounds are of course conceivable.

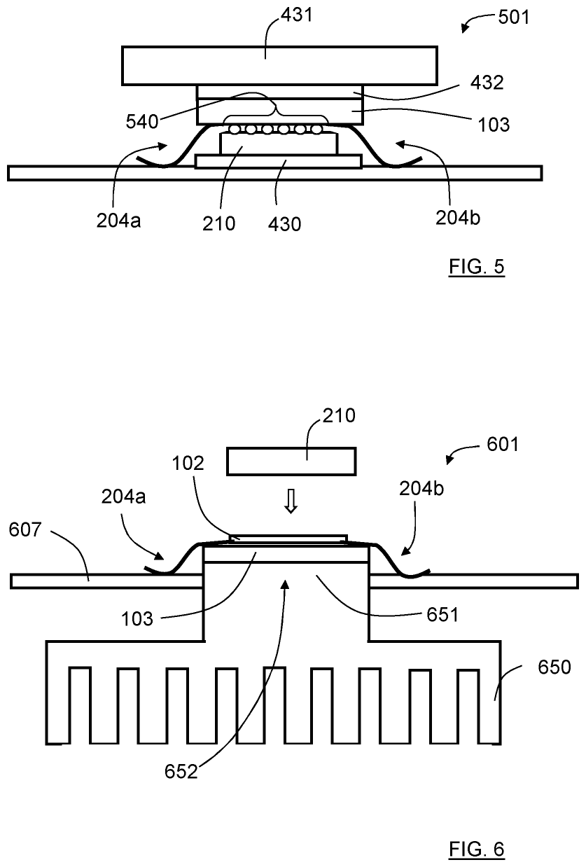

According to some aspects, with reference to FIG. 5 that illustrates a fourth example, the package arrangement 501 corresponds to the one discussed previously with reference to FIG. 4, where furthermore the IC 502 comprises ball grid array (BGA) connections that are connected to the flexible conductor tracks 106a, 106b of the flexible conductor device 104; 204a, 204b. This will improve the cooling which normally is a problem for BGA packages.

When discussing the second example above, it was mentioned that the metal insert 320 can provide heat dissipation, possibly to a cooling flange that is in thermal contact with the metal insert 320. According to some aspects, with reference to FIG. 5 that illustrates a fourth example, the PCB 607 comprises an aperture 652 through which at least one protruding part 651 of an external cooling flange structure 650, 750 protrudes, where the metal carrier 103 at least partly is adapted to be placed on a part of the protruding part 651; 751a, 751b. This is advantageous, for example when cooling requirements are high and if the package arrangement 501 is used in a larger structure with integrated cooling flanges. The term external cooling flange structure refers to a cooling flange structure that extends away from the immediate vicinity of the PCB, and can according to some aspects extend into an outdoor environment.

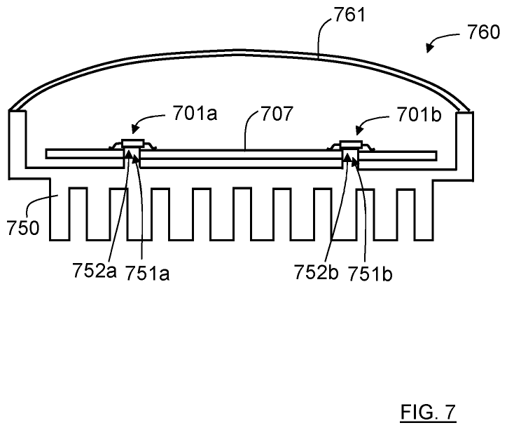

An example of this is disclosed in FIG. 7 in combination with FIG. 1, where a microwave link transceiver arrangement 760 comprises an external cooling flange structure 750, a radome 761 that is connected to the external cooling flange structure 750, and a PCB 707 that is enclosed by the external cooling flange structure 750 and the radome 761. The PCB 707 comprises at least one aperture 752a, 752b through which at least one protruding part 751a, 751b of the external cooling flange structure 750 protrudes. The metal carrier 103 of at least one package arrangement 701a, 701b is adapted to at least partly be placed on a part of a corresponding protruding part 751a, 751b, and the conductor tracks 106a, 106b are adapted to be electrically connected to external conductor tracks 108a, 108b that are provided on the PCB 707. In this example there are two apertures, two protruding parts 751a, 751b and two package arrangement 701a, 701b, but there can of course be any number of these co-operating features.

It is to be noted that the examples disclosed above comprise different varieties and sub-examples. Furthermore, the example can be combined in any suitable manner, for example the IC can comprise BGA connections for all examples, and different constellations of intermediate resilient thermally conductive material can be applied. For example, the example described with reference to FIG. 4 can comprise the metal heat sink and intermediate materials as options, one or more of these not being necessary as follows from the above.

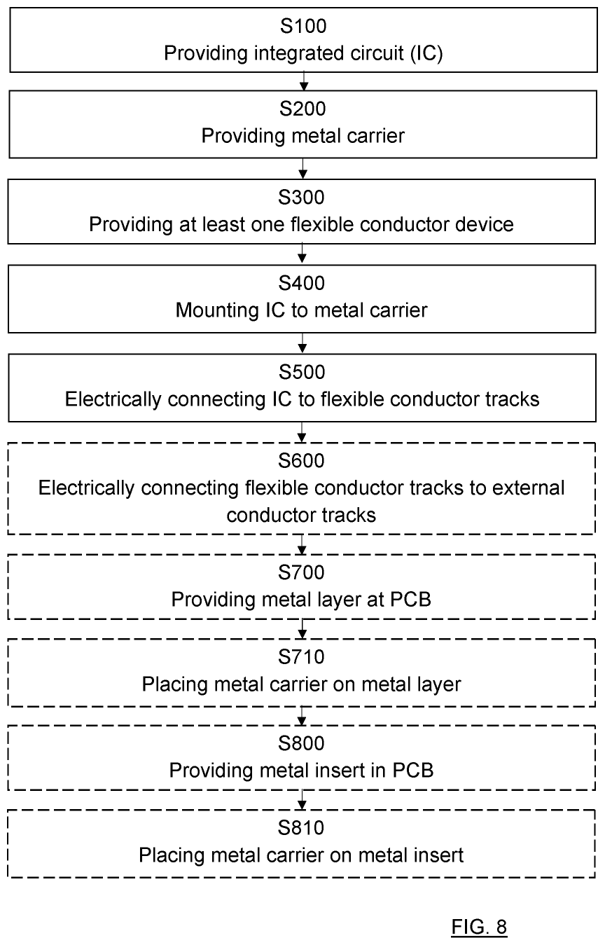

With reference to FIG. 8, the present disclosure also relates to method for assembling electronic component package arrangement 101, where the method comprises providing S100 an integrated circuit 102 (IC), providing S200 a metal carrier 103; and providing S300 at least one flexible conductor device 104; 204a, 204b. The IC 102 has an IC mounting surface Sᵢ and the metal carrier 103 has a carrier mounting surface S_{c} with an area that exceeds an area of the IC mounting surface Sᵢ. The method further comprises mounting S400 the IC mounting surface Sᵢ to the carrier mounting surface S_{c}, where the flexible conductor device 104; 204a, 204b is placed between the IC 102 and the metal carrier 103. The flexible conductor device 104; 204a, 204b comprises a metallization 106a, 106b that is carried on a flexible dielectric carrier material 105, where the metallization forms flexible conductor tracks 106a, 106b. The method further comprises electrically connecting S500 the IC 102 to the flexible conductor tracks 106a, 106b, where the flexible conductor tracks 106a, 106b lead from the IC 102 to a position distanced from the metal carrier 3 such that the flexible conductor tracks 106a, 106b can be electrically connected to an external device 107.

According to some aspects, the external device is a printed circuit board 107 (PCB) where the method comprises electrically connecting S600 the flexible conductor tracks 106a, 106b to external conductor tracks 108a, 108b that are provided on the PCB 107.

According to some aspects, the method comprises providing a cover part 210, adapted to cover the IC 102.

According to some aspects, the method comprises providing S700 a metal layer 211 at the PCB 107, and at least partly placing S710 the metal carrier 103 on the metal layer 211.

According to some aspects, the method comprises providing S800 a metal insert 320 in the PCB 107, and at least partly placing S810 the metal carrier 103 on the metal insert 320.

According to some aspects, the method comprises providing a first intermediate resilient thermally conductive material 321, and placing the first intermediate resilient thermally conductive material 321 on a side of the metal carrier 103 that faces the PCB 107.

According to some aspects, the method comprises providing a second intermediate resilient thermally conductive material 430, and placing the second intermediate resilient thermally conductive material 430 between the cover part 210 and the PCB 107.

According to some aspects, the method comprises providing a metal heatsink 431 and thermally connecting the metal heatsink 431 to the metal carrier 103, the metal heatsink 431 being larger than the metal carrier 103.

According to some aspects, the method comprises providing a third intermediate resilient thermally conductive material 432 and placing the third intermediate resilient thermally conductive material 432 between the metal heatsink 431 and the metal carrier 103.

According to some aspects, at least one resilient thermally conductive material 321, 430, 432 is constituted by silicon rubber or a thermally conductive paste.

According to some aspects, the method comprises providing an aperture 652, 752a, 752b in the PCB 607, 707, through which aperture 652, 752a, 752b at least one protruding part 651; 751a, 751b of an external cooling flange structure 650, 750 protrudes, and at least partly placing the metal carrier 103 on a part of the protruding part 651; 751a, 751b.

The present disclosure is not limited to the above, but may vary freely within the scope of the appended claims. For example, flexible dielectric carrier material 105 can be any material that is suitable to carry electrically conducting tracks.

In the present context, the PCB does not have to be a traditional PCB, but can be any layered structure such as for example MMIC (Monolithic Microwave Integrated Circuit), RFIC (Radio-Frequency Integrated Circuit), substrate, etc.

The IC can be any kind of integrated circuit and can according to some aspects, comprise a processor, an amplifier, passive components such as filters and a combination of these, the IC being adapted for any of DC, low frequency, high frequency and microwave applications, as well as a combination of two or more of these.

The metal parts can be made in any suitable metal or metals such as form example copper, alumina and alloys such as Invar.

According to some aspects, the electronic component package arrangement is suitable for surface-mounting, in particular in a pick-and-place process.

1. An electronic component package arrangement comprising an integrated circuit, IC, a metal carrier and at least one flexible conductor device, where the IC has an IC mounting surface (Sᵢ) and the metal carrier has a carrier mounting surface (S_{c}) with an area that exceeds an area of the IC mounting surface (Sᵢ), where the IC mounting surface (Sᵢ) is mounted to a part of the carrier mounting surface (S_{c}), wherein the flexible conductor device is placed between the IC and the metal carrier and comprises a metallization that is carried on a flexible dielectric carrier material, where the metallization forms flexible conductor tracks to which the IC is electrically connected, the flexible conductor tracks leading from the IC to a position distanced from the metal carrier such that the flexible conductor tracks can be electrically connected to an external device.

2. The package arrangement according to claim 1, wherein the external device is a printed circuit board, PCB, where the flexible conductor tracks are adapted to be electrically connected to external conductor tracks that are provided on the PCB.

3. The package arrangement according to claim 2, wherein where the package arrangement comprises a cover part, adapted to cover the IC.

4. The package arrangement according to claim 2, wherein the PCB comprises a metal layer onto which the metal carrier at least partly is adapted to be placed.

5. The package arrangement according to claim 2, wherein the PCB comprises a metal insert onto which the metal carrier at least partly is adapted to be placed.

6. The package arrangement according to claim 4, wherein the package arrangement comprises a first intermediate resilient thermally conductive material placed on a side of the metal carrier that faces the PCB.

7. The package arrangement according to claim 3, wherein the package arrangement comprises a second intermediate resilient thermally conductive material placed between the cover part and the PCB.

8. The package arrangement according to claim 3, wherein the package arrangement comprises a metal heatsink that is thermally connected to the metal carrier, the metal heatsink being larger than the metal carrier.

9. The package arrangement according to claim 8, wherein the package arrangement comprises a third intermediate resilient thermally conductive material placed between the metal heatsink and the metal carrier.

10. The package arrangement according to claim 6, wherein at least one resilient thermally conductive material is constituted by silicon rubber or a thermally conductive paste.

11. The package arrangement according to claim 1, wherein the PCB comprises an aperture through which at least one protruding part of an external cooling flange structure protrudes, where the metal carrier at least partly is adapted to be placed on a part of the protruding part.

12. The package arrangement according to claim 1, wherein the IC comprises ball grid array, BGA, connections that are connected to the flexible conductor tracks of the flexible conductor device.

13. A microwave link transceiver arrangement comprising an external cooling flange structure, a radome that is connected to the external cooling flange structure, and a PCB that is enclosed by the external cooling flange structure and the radome, where the PCB comprises at least one aperture through which at least one protruding part of the external cooling flange structure protrudes, where the metal carrier of at least one package arrangement at least partly is adapted to be placed on a part of a corresponding protruding part, wherein:
the at least one package arrangement comprising an integrated circuit (IC), a metal carrier, and at least one flexible conductor device, where the IC has an IC mounting surface (Sᵢ) and the metal carrier has a carrier mounting surface (S_{c}) with an area that exceeds an area of the IC mounting surface (Sᵢ), where the IC mounting surface (Sᵢ) is mounted to a part of the carrier mounting surface (S_{c}), wherein the flexible conductor device is placed between the IC and the metal carrier and comprises a metallization that is carried on a flexible dielectric carrier material, where the metallization forms flexible conductor tracks to which the IC is electrically connected, the flexible conductor tracks leading from the IC to a position distanced from the metal carrier such that the flexible conductor tracks can be electrically connected to an external device; and
the flexible conductor tracks are adapted to be electrically connected to external conductor tracks that are provided on the PCB.

14. A method for assembling electronic component package arrangement, where the method comprises:
providing an integrated circuit, IC;
providing a metal carrier; and
providing at least one flexible conductor device;
where the IC has an IC mounting surface (Sᵢ) and the metal carrier has a carrier mounting surface (S_{c}) with an area that exceeds an area of the IC mounting surface (Sᵢ), where the method further comprises:
mounting the IC mounting surface (Sᵢ) to the carrier mounting surface (S_{c}), wherein the flexible conductor device is placed between the IC and the metal carrier;
where the flexible conductor device comprises a metallization that is carried on a flexible dielectric carrier material, where the metallization forms flexible conductor tracks, where the method further comprises:
electrically connecting the IC to the flexible conductor tracks;
where the flexible conductor tracks lead from the IC to a position distanced from the metal carrier such that the flexible conductor tracks can be electrically connected to an external device.

15. The method according to claim 14, wherein the external device is a printed circuit board, PCB, where the method comprises electrically connecting the flexible conductor tracks to external conductor tracks that are provided on the PCB.

16. The method according to claim 15, wherein the method comprises providing a cover part, adapted to cover the IC.

17. The method according to claim 15, wherein the method comprises providing a metal layer at the PCB, and at least partly placing the metal carrier on the metal layer.

18. The method according to claim 15, wherein the method comprises providing a metal insert in the PCB, and at least partly placing the metal carrier on the metal insert.

19. The method according to claim 17, wherein the method comprises providing a first intermediate resilient thermally conductive material, and placing the first intermediate resilient thermally conductive material on a side of the metal carrier that faces the PCB.

20. The method according to claim 16, wherein the method comprises providing a second intermediate resilient thermally conductive material, and placing the second intermediate resilient thermally conductive material between the cover part and the PCB.

21-24. (canceled)
